(19) United States
(12) Patent Application Publication
(10) Pub. No.: US 2003/0036233 A1
(43) Pub. Date: Feb. 20, 2003

(54) Method of forming a word line in an embedded dynamic random access memory

(75) Inventor: Terry Chung-Yi Chen, Taipei (TW)

Correspondence Address: LOWE HAUPTMAN, GILMAN & BERNER, LLP, Suite 310, 1700 Diagonal Road, Alexandria, VA, 22314, US

(73) Assignee: UNITED MICROELECTRONICS CORP.

(21) Appl. No.: 09/930,303

(22) Filed: Aug. 16, 2001

(51) Int. Cl. H01L 21/336; H01L 21/4763

(52) U.S. Cl. 438/261; 438/265; 438/651

(57) ABSTRACT

This invention relates to a method of forming a word line, more particularly, to the method of forming a word line in an embedded dynamic random access memory (eDRAM). The present invention uses a sandwich structure in silicon (Si)/tungsten silicon (WSi)/buffer layer to be the structure of the word line in the embedded dynamic random access memory to keep the enough thickness of the nitride layer, which is on the gate, and to proceed the self-aligned contact process in the embedded dynamic random access memory region in the following process to increase the efficiency of the process. The gate, which is formed by using the present invention method and is proceed the metal salicide process in the logic region that is in the embedded dynamic random access memory, will keep the low resistance of the word line and will increase the efficiency of the embedded dynamic random access memory.

### BACKGROUND OF THE INVENTION

1. Field of the Invention

This invention relates to a method of forming a word line, more particularly, to the method of forming a word line in an embedded dynamic random access memory (eDRAM). The present invention uses a sandwich structure in silicon (Si)/tungsten silicon (WSi)/buffer layer to be the structure of the word line in the embedded dynamic random access memory to increase the efficiency of the process and to increase the efficiency of the embedded dynamic random access memory.

2. Description of the Prior Art

In the integrated circuit (IC) industry, manufacturers are currently imbedding dynamic random access memory (DRAM) arrays on the same substrate as CPU cores or other logic devices. This technology is being referred to as embedded DRAM (eDRAM). Embedded DRAM is likely to provide microcontroller (MCU) and other embedded controllers faster access to larger capacities of on-chip memory at a lower cost than that currently available using conventional embedded static random access memory (SRAM) and/or electrically erasable programmable read only memory (EEPROM).

The embedded dynamic random access memory means that the dynamic random access memory is placed in a logic circuit to increase the access rate of the data of the dynamic random access memory andto increase the efficiency of the semiconductor devices. In the embedded dynamic random access memory, the dynamic random access memory is used to memorize the data and the logic circuit is used to operate the data.

Referring to FIG. 1, this shows a diagram in a structure of the traditional embedded dynamic random access memory. A wafer, which comprises a substrate 20 and a shallow trench isolation (STI) layer 25, is provided at first when using the traditional method forms the embedded dynamic random access memory. The shallow trench isolation layers 25 are filled of the insulating materials and the surface of the substrate 20 and the shallow trench isolation layers 25 has been proceed the chemical mechanical polishing (CMP) procedure to become a level and smooth surface. Then the wafer is divided into a dynamic random access memory region 10 and a logic circuit region 15 and a silicon layer 30 is formed on the substrate 20 and the shallow trench isolation layers 25. Then a titanium silicide layer 35 is formed on the silicon layer 30 by using a sputtering procedure and a nitride layer 45 is formed on the titanium silicide layer 35. After defining the locations of the gates in the dynamic random access memory region 10 and in the logic circuit region 15, the partial silicon layer 30, the partial titanium silicide layer 35, and the partial nitride layer 45 are removed by using a photolithography and an etching procedure to form the gates in the dynamic random access memory region 10 and in the logic circuit region 15 and the partial titanium silicide layer, which is on the substrate 20 in the logic circuit region 15, is retained. The gates comprise a silicon layer 30, the titanium silicide layer 35, and the nitride layer 45. Then the spacers are formed on the sidewalls of the gates, which are in the dynamic random access memory region 10 and in the logic circuit region 15. Nitride is most used to be the material of the spacers. The gates, which are formed in the dynamic random access memory region 10 and in the logic circuit region 15, will be connected to be a line and to become the word line.

Then a dielectric layer 50 is formed on the gates, spacers 40, shallow trench isolation layers 25, titanium silicide layer 35, and the substrate 20. After proceeding a chemical mechanical polishing procedure, the surface of the dielectric layer 50 will become a level and smooth surface. At last, the partial dielectric layer 50 is removed by using a photolithography and an etching procedure to form a via contact between the gates, which are in the dynamic random access memory region 10.

The structure of the gates, which are used to be the word line, is silicon layer 30/titanium silicide layer 35/nitride layer 45 in the embedded dynamic random access memory, which is formed by using the traditional method. However, there is a higher stress between the nitride layer 45 and the titanium silicide layer 35. Therefore, the thickness of the nitride layer 45 will be limited to prevent the break defects occurring at the place between the nitride layer 45 and the titanium silicide layer 35 to cause the leakage defects because of the over high stress. Because the thickness of the nitride layer 45 is limited, the via contact 55 will not formed by using the self-aligned etching procedure in the dynamic random access memory region 10, to avoid the nitride layer 45 being over etched to expose the titanium silicide layer 35 and to occur the leakage defects. Therefore, the via contact 55 will be formed by using the complex procedure, such as: the poly spacer/hard mask etching. These complex procedures will increase the steps of the procedure and will decrease the proceeding efficiency of the procedure.

### SUMMARY OF THE INVENTION

In accordance with the above-mentioned invention backgrounds, the traditional method will cause the leakage defects in the embedded dynamic random access memory to affect the qualities of the semiconductor device and to decrease the efficiency of the procedure. The main objective of the present invention is to keep the thickness of the nitride layer, which is on the gate, and to make the self-aligned contact procedure to be proceed in the dynamic random access memory region in the following procedure to increase the efficiency of the procedure by using the sandwich structure in silicon/tungsten silicon/buffer layer to be the structure of the word line in the embedded dynamic random access memory.

The second objective of this invention is to decrease the resistance of the word line, which is in the logic circuit region, by using the sandwich structure in silicon/tungsten silicon/buffer layer to be the structure of the word line in the embedded dynamic random access memory and treating the word line in a self-aligned metal silicide procedure.

The third objective of this invention is to increase the qualities of the semiconductor device by using the sandwich structure in silicon/tungsten silicon/buffer layer to be the structure of the word line in the embedded dynamic random access memory.

It is a further objective of this invention is to decrease the cost of the procedure by using the sandwich structure in silicon/tungsten silicon/buffer layer to be the structure of the word line in the embedded dynamic random access memory.

In according to the foregoing objectives, the present invention provides a method for forming the embedded dynamic random access memory by using the sandwich structure in silicon/tungsten silicon/buffer layer to be the structure of the word line in the embedded dynamic random access memory to keep the enough thickness of the nitride layer, which is on the gate, and to proceed the self-aligned contact procedure in the dynamic random access memory region in the following procedure to increase the efficiency of the procedure. The present invention can also keep the low resistance of the word line, which is in the logic circuit region, and increase the access rate of the data of the embedded dynamic random access memory. The present invention can further increase the qualities of the semiconductor devices and decrease the cost of the procedure.

### BRIEF DESCRIPTION OF THE DRAWINGS

In the accompanying drawing forming a material part of this description, there is shown:

FIG. 1 shows a diagram in a structure of the traditional embedded dynamic random access memory;

FIG. 2 shows a diagram in forming a silicon layer, a tungsten silicon layer, buffer layer, and the nitride layer on a substrate and shallow trench isolation layers;

FIG. 3 shows a diagram in forming the first mask layer on the nitride layer, which is on the location of the plural first gates in the dynamic random access memory region and removing the partial nitride layer;

FIG. 4 shows a diagram in forming the second mask layer on the buffer layer, which is on the location of the gates in the logic circuit region and removing the partial silicon layer, the tungsten silicon layer, and the buffer layer to form the gates in the dynamic random access memory region and the logic circuit region;

FIG. 5 shows a diagram in forming a spacer layer on the substrate, the shallow trench isolation layers, the plural first gates, and the plural second gates;

FIG. 6 shows a diagram in forming spacers on the sidewalls of the plural first gates, which are in the dynamic random access memory region and forming spacers on the sidewalls of the plural second gates, which are in the logic circuit region;

FIG. 7 shows a diagram in forming the third mask layer on the gates, the spacers, and the substrate which are in the dynamic random access memory region and forming a metal layer on the third mask layer, the shallow trench isolation layers, the gate, which is in the logic circuit region, the spacers, which are in the logic circuit region, and the substrate, which is in the logic circuit region;

FIG. 8 shows a diagram in forming a metal silicide on the substrate and the buffer layer which are in the logic circuit region and removing the third mask layer;

FIG. 9 shows a diagram in forming a dielectric layer on the substrate, the spacers, the nitride layer, the metal silicide layer, and the shallow trench isolation layers; and

FIG. 10 shows a diagram in forming a via contact between the gates which are in the dynamic random access memory region by using the self-aligned etching procedure to remove the partial dielectric layer.

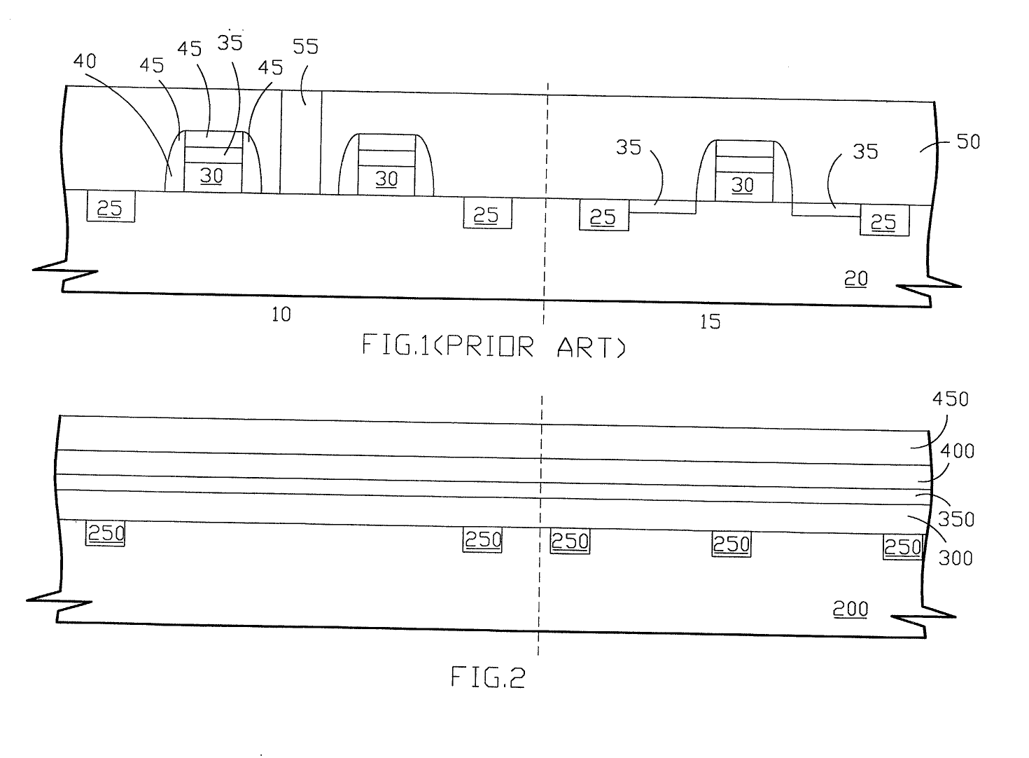

### DESCRIPTION OF THE PREFERRED EMBODIMENT

The foregoing aspects and many of the intended advantages of this invention will become more readily appreciated as the same becomes better understood by reference to the following detailed description, when taken in conjunction with the accompanying drawings, wherein:

The semiconductor devices, which are in the logic circuit, are interconnected by using the word line and the bit line. The objective of the word line is to define the location of the signals and the objective of the bit line is to judge the types of the signal. Therefore, the word line connects with the gate of the semiconductor device and the bit line connects with the source/drain region of the semiconductor device.

The embedded dynamic random access memory is also divided into two regions. One is a dynamic random access memory region and the other is a logic circuit region. The objective of the dynamic random access memory is to memorize the data and the objective of the logic circuit is to operate the data. Therefore, the gates which are in the logic circuit region must be interconnected with the metal wire to increase the rate in operating the data and the gates which are in the dynamic random access memory region must be isolated with each other to prevent the leakage defects and to prevent the data, which were saved in the dynamic random access memory region, to be lost. The gates of the dynamic random access memory region and the gates of the logic circuit region are all called the word line.

Referring to FIG. 2, A wafer, which comprises a substrate 200 and shallow trench isolation layers 250, is provided at first. The shallow trench isolation layers 250 are filled of the insulating materials and the surface of the substrate 20 and the shallow trench isolation layers 25 has been proceed the chemical mechanical polishing (CMP) procedure to become a level and smooth surface. Then a silicon layer 300 is formed on the substrate 200 and the shallow trench isolation layers 250 and a tungsten silicon layer 350 is formed on the silicon layer 300. At last, a buffer layer 400 is formed on the tungsten silicon layer 350 and the nitride layer 450 is formed on the buffer layer 400. Silicon is usually used to be the material of the buffer layer 400 to cooperate the needs of the procedure. The nitride silicon is most used to be the material of the nitride layer 450.

Referring to FIG. 3, the wafer is divided into two regions. One is a dynamic random access memory region 100 and the other is a logic circuit region 150. Then the location of the gates, which are in the dynamic random access memory region 100, are defined and the first mask layer 500 is formed on the nitride layer 450, which is on the location of the gates in the dynamic random access memory region 100. After removing the partial nitride layer 450 by using an etching procedure and removing the first mask layer 500, nitride layers 450 are formed on the location of the gates in the dynamic random access memory region 100 and on the buffer layers 400.

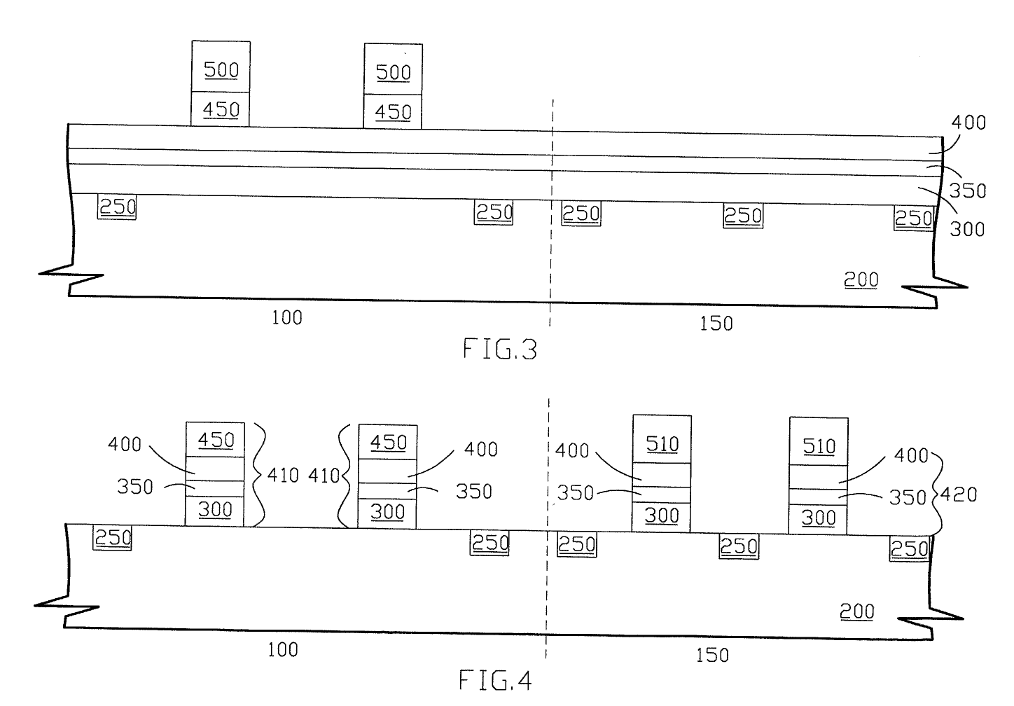

Referring to FIG. 4, then the location of the gate, which is in the logic circuit region 150, is decided and the second mask layer 510 is formed on the location of the gate in the logic circuit region 150 and on the buffer layer 400. After removing the partial buffer layer 400, the partial tungsten silicon layer 350, and the partial silicon layer 300 by using an etching procedure and removing the second mask layer 510, the plural first gates 410 are formed in the dynamic random access memory region 100 and the plural second gates 420 are formed in the logic circuit region 150. The structure of the plural first gates 410 in the dynamic random access memory region 100 is silicon layer/tungsten silicon layer/buffer layer/nitride layer. The structure of the plural second gates in the logic circuit region 150 is the sandwich structure in silicon layer/tungsten silicon layer/buffer layer. Because there are the nitride layers on the location of the dynamic random access memory region 100 and on the buffer layer 400 to be the hard mask layer. Therefore, in the removing the partial buffer layer 400, the partial tungsten silicon layer 350, and the partial silicon layer 300 procedure, the second mask layer 510 does not have to be used to protect the buffer layer 400, the tungsten silicon layer 350, and the silicon layer 300 which are on the location of the plural first gates 410 in the dynamic random access memory region 100.

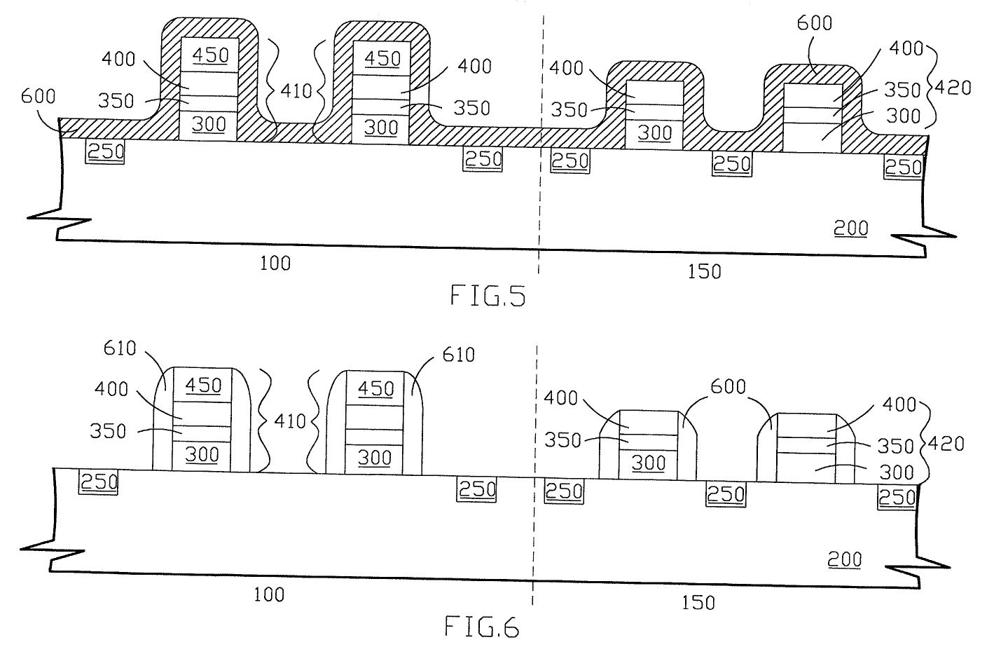

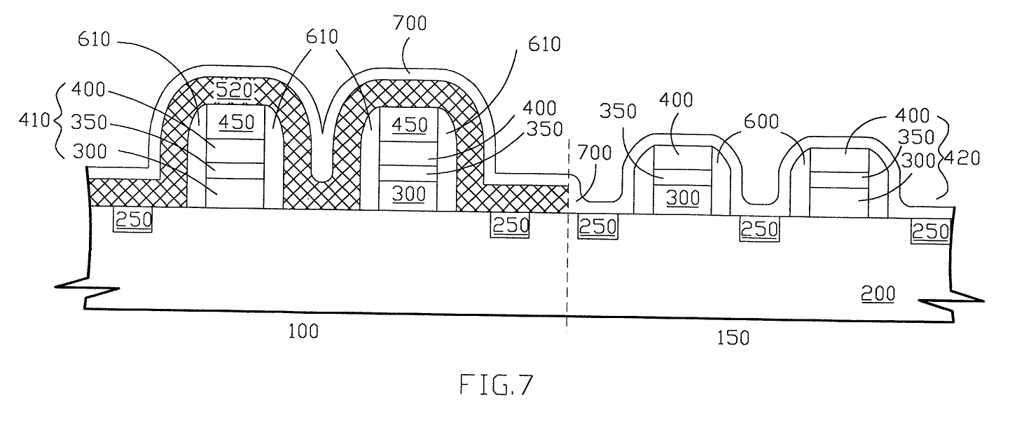

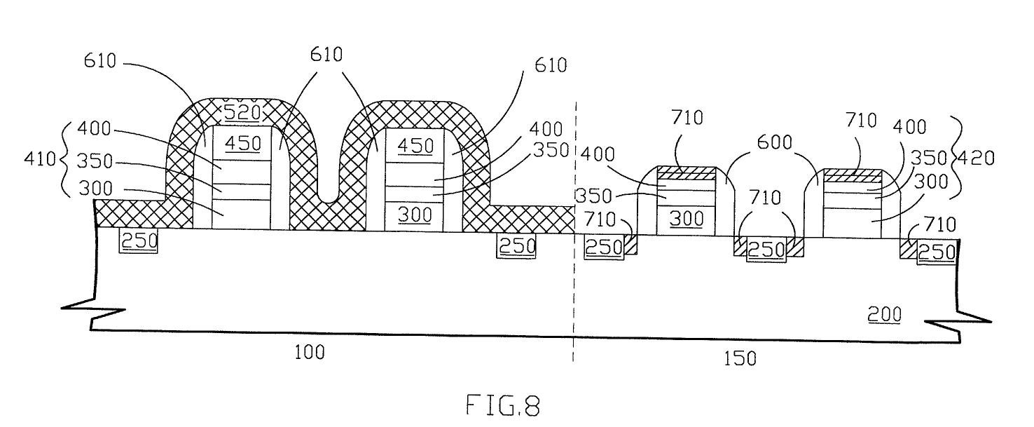

Referring to FIG. 5, then a spacer layer is formed on the substrate 200, the shallow trench isolation layers 250, the plural first gates410, and the plural second gates 420. After an etching procedure to remove the partial spacer layer, the sapcers 610 are formed on the sidewalls of the plural first gates 410, which are in the dynamic random access memory region 100, and the plural second gates 420, which are in the logic circuit region 150 (referring to FIG. 6).

Then the third mask layer is formed on the first plural gates 410, the second plural gates 420, spacers 600 and 610, the shallow trench isolation layers 250, and the substrate 200. After passing through a photolithography procedure and an etching procedure to remove the partial third mask layer, the third mask layer 520 is formed on the first plural gates 410, which are in the dynamic random access memory region 100, spacers 610, and the substrate 200 (referring to FIG. 7). The material of the third mask layer is silicon nitride or silicon dioxide. Then a metal layer 700 is formed on the third mask layer 520, the shallow trench isolation layers 250, the plural second gates 420 which are in the logic circuit region 150, the spacers 610 which are in the logic circuit region 150, and the substrate 200 which is in the logic circuit region 150. The chemical vapor deposition method or the direct current magnetron sputtering method is most used to form the metal layer 700. Then the wafer is placed into the chamber to proceed the first rapid thermal process (RTP). The metal layer 700 will react with the silicon, which is at the contact region, to form the silicide layer. The using temperature of the silicide process is about 500 to 700° C. The structure of the metal silicide which is formed in the first rapid thermal process is a structure with higher resistivity. Referring to FIG. 15, the unreacted and the remained metal layer 700 is removed by applying the RCA cleaning method. Therefore, the silicide layers 710 are existed on the top of the substrate 200 and the buffer layer 400 which are in the logic circuit region 150. Finally, the third mask layer 520 is removed and the second rapid thermal process is performed to transform higher resistivity of the silicide structure into lower resistivity of the silicide structure. The using temperature of the second rapid thermal process is about 750 to 850° C. The material of the metal layer 700 can be titanium, cobalt, and platinum.

Titanium is the most common used metallic material for the current salicide process. Basically, titanium is a fine oxygen gettering material, where under an appropriate temperature titanium and silicon at MOS device source/drain and gate regions are easily mutually diffused to form a titanium silicide with very low resistance.

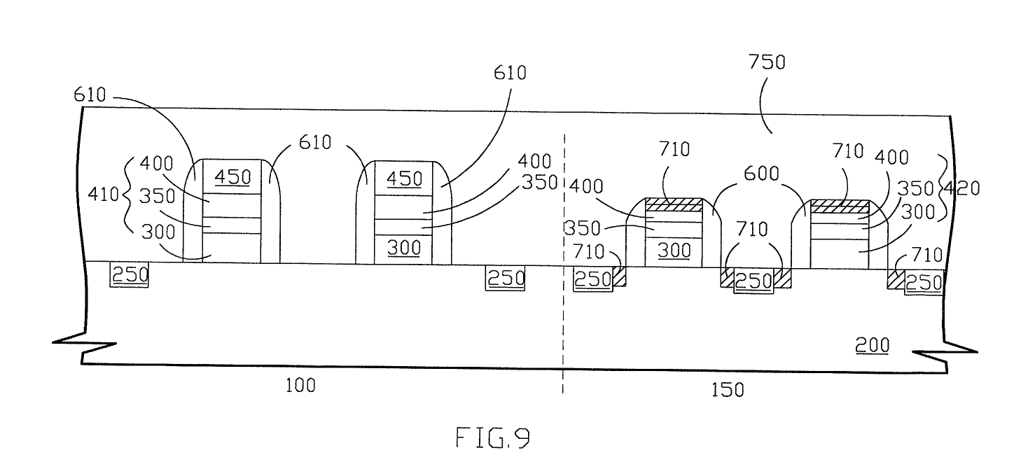

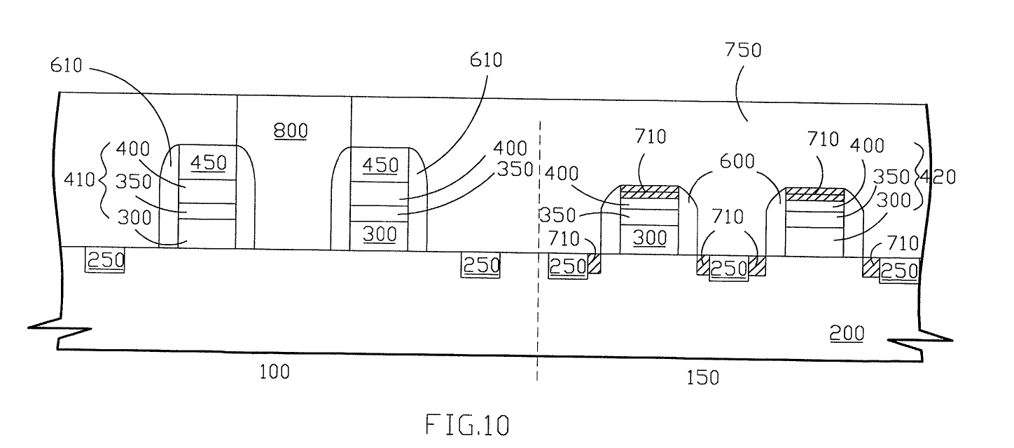

Referring to FIG. 9, after removing the third mask layer 520, a dielectric layer 750 is formed on the substrate 200, the spacers 610, the nitride layer 450, the metal silicide layer 710, and the shallow trench isolation layers 250. The surface of the dielectric layer 750 is polished by using the chemical mechanical polishing procedure to become a level and smooth surface. Referring to FIG. 10, the partial dielectric layer 750 is removed by using the self-aligned etching procedure to form a via contact 800 between the plural first gates 410 in the dynamic random access memory region 100 and the procedure of the present invention is finished. The self-aligned etching procedure means that the forth mask layer is formed on the surface of the partial dielectric layer 750 and the partial dielectric layer 750 is removed to form the via contact 800 between the plural first gates 410 in the dynamic random access memory region 100.

Because the stress at the place between the buffer layer and the nitride layer is lower than the stress at the place between the metal silicide layer and the nitride layer. The metal silicide layer comprise titanium silicon or tungsten silicon. Therefore, the method of the present invention can control the thickness of the nitride layer to become thicker. The break defects and the leakage defect will not be occurred at the place between the nitride layer and the buffer layer by using the method of the present invention. Because the thickness of the nitride layer, which is on the plural first gates in the dynamic random access memory region, is thicker, the thicker nitride layer will used to be the hard mask layer to protect the plural first gates, which are in the dynamic random access memory region and to avoid the tungsten layer being exposed to occur the leakage defect if the self-aligned etching procedure is used in the back-end procedure. The thickness of the nitride layer is 1200 to 1800 angstroms in usual. Using self-aligned etching procedure to form the via contact will decrease the steps of the procedure and will decrease the cost of the procedure. Using the method of the present invention to form the metal silicide layer in the logic circuit region will decrease the resistance of the word line and will increase the qualities of the semiconductor device.

In accordance with the present invention, the present invention provides a method for forming the embedded dynamic random access memory by using the sandwich structure in silicon/tungsten silicon/buffer layer to be the structure of the word line in the embedded dynamic random access memory to keep the thickness of the nitride layer, which is on the gate, and to proceed the self-aligned contact procedure in the dynamic random access memory region in the following procedure to increase the efficiency of the procedure. The present invention can also keep the low resistance of the word line, which is in the logic circuit region, and increase the access rate of the data of the embedded dynamic random access memory. The present invention can further increase the qualities of the semiconductor devices and decrease the cost of the procedure.

Although specific embodiments have been illustrated and described, it will be obvious to those skilled in the art that various modifications may be made without departing from what is intended to be limited solely by the appended claims.

What is claimed is:

1. A method of forming a word line in an embedded dynamic random access memory, said method comprises:
providing a wafer, wherein said wafer comprises a substrate and said substrate comprises a shallow trench isolation layer;
forming a silicon layer on said substrate and said shallow trench isolation layer;
forming a tungsten silicon layer on said silicon layer;
forming a buffer layer on said tungsten silicon layer;
forming a nitride layer on said buffer layer and dividing said wafer into a first region and a second region;
forming a first mask layer on said partial nitride layer in said first region;
removing said partial nitride layer;
removing said first mask layer;
forming a second mask layer on said partial buffer layer in said second region;
removing said partial buffer layer, said partial tungsten silicon layer; and said silicon layer;
removing said second mask layer to form a plural first gates in said first region and a plural second gates in said second region;
forming a spacer on a sidewall of said plural first gates and on a sildewall of said plural second gates;
forming a third mask layer on said plural first gates, said spacer which is on said sidewall of said plural first gates, and said substrate which is in said first region;
forming a metal layer on said third mask layer, said shallow trench isolation layer; said plural second gates, said spacer which is on said sidewall of said plural second gates, and said substrate which is in said second region;
proceeding a first rapid thermal process to form a metal silicide layer on said plural second gates and said substrate which is in said second region;
removing said metal layer;
removing said third mask layer;
forming a dielectric layer on said substrate, said spacer said nitride layer, said metal silicide layer, and said shallow trench isolation layer; and
removing said partial dielectric layer to form a via contact between said plural first gates.

2. The method according to claim 1, wherein said first region is a dynamic random access memory region.

3. The method according to claim 1, wherein said second region is a logic circuit region.

4. The method according to claim 1, wherein said buffer layer is a silicon layer.

5. The method according to claim 1, wherein said a material of said metal layer is titanium.

6. The method according to claim 1, wherein said a material of said metal layer is cobalt.

7. The method according to claim 1, wherein said a material of said metal layer is platinum.

8. A method of forming a word line in an embedded dynamic random access memory, said method comprises:
providing a wafer, wherein said wafer comprises a substrate and said substrate comprises a shallow trench isolation layer;
forming a first silicon layer on said substrate and said shallow trench isolation layer;
forming a tungsten silicon layer on said first silicon layer;
forming a second silicon layer on said tungsten silicon layer;
forming a nitride layer on said second silicon layer and dividing said wafer into a first region and a second region;
forming a first mask layer on said partial nitride layer in said first region;
removing said partial nitride layer;
removing said first mask layer;
forming a second mask layer on said partial second silicon layer in said second region;
removing said partial second silicon layer, said partial tungsten silicon layer; and said silicon layer;
removing said second mask layer to form a plural first gates in said first region and a plural second gates in said second region;
forming a spacer layer on said plural first gates, said plural second gates, said substrate, and said shallow trench isolation layer;
removing said partial spacer layer to form a spacer on a sidewall of said plural first gates and on a sildewall of said plural second gates;
forming a third mask layer on said plural first gates, said spacer which is on said sidewall of said plural first gates, and said substrate which is in said first region;
forming a metal layer on said third mask layer, said shallow trench isolation layer; said plural second gates, said spacer which is on said sidewall of said plural second gates, and said substrate which is in said second region;
proceeding a first rapid thermal process to form a metal silicide layer on said plural second gates and said substrate which is in said second region;
removing said metal layer and proceeding a second rapid thermal process;
removing said third mask layer;
forming a dielectric layer on said substrate, said spacer said nitride layer, said metal silicide layer, and said shallow trench isolation layer;
polishing a surface of said dielectric layer; and
removing said partial dielectric layer to form a via contact between said plural first gates.

9. The method according to claim 8, wherein said first region is a dynamic random access memory region.

10. The method according to claim 8, wherein said second region is a logic circuit region.

11. The method according to claim 8, wherein said a material of said metal layer is titanium.

12. The method according to claim 8, wherein said a material of said metal layer is cobalt.

13. The method according to claim 8, wherein said a material of said metal layer is platinum.

14. A method of forming a word line in an embedded dynamic random access memory, said method comprises:
providing a wafer, wherein said wafer comprises a substrate and said substrate comprises a shallow trench isolation layer;
forming a first silicon layer on said substrate and said shallow trench isolation layer;
forming a tungsten silicon layer on said first silicon layer;
forming a second silicon layer on said tungsten silicon layer;
forming a nitride layer on said second silicon layer and dividing said wafer into a dynamic random access memory region and a logic circuit region;
forming a first mask layer on said partial nitride layer in said dynamic random access memory region;
removing said partial nitride layer;
removing said first mask layer;
forming a second mask layer on said partial second silicon layer in said logic circuit region;
removing said partial second silicon layer, said partial tungsten silicon layer; and said silicon layer;
removing said second mask layer to form a plural first gates in said dynamic random access memory region and a plural second gates in said logic circuit region;
forming a spacer layer on said plural first gates, said plural second gates, said substrate, and said shallow trench isolation layer;
removing said partial spacer layer to form a spacer on a sidewall of said plural first gates and on a sildewall of said plural second gates;
forming a third mask layer on said plural first gates, said spacer which is on said sidewall of said plural first gates, and said substrate which is in said dynamic random access memory region;
forming a metal layer on said third mask layer, said shallow trench isolation layer; said plural second gates, said spacer which is on said sidewall of said plural second gates, and said substrate which is in said logic circuit region;
proceeding a first rapid thermal process to form a metal silicide layer on said plural second gates and said substrate which is in said logic circuit region;
removing said metal layer and proceeding a second rapid thermal process;
removing said third mask layer;
forming a dielectric layer on said substrate, said spacer said nitride layer, said metal silicide layer, and said shallow trench isolation layer;
polishing a surface of said dielectric layer; and
removing said partial dielectric layer to form a via contact between said plural first gates.

15. The method according to claim 14, wherein said a material of said metal layer is titanium.

16. The method according to claim 14, wherein said a material of said metal layer is cobalt.

17. The method according to claim 14, wherein said a material of said metal layer is platinum.
